(19) United States
(12) Patent Application Publication
(10) Pub. No.: US 2014/0089609 A1
(43) Pub. Date: Mar. 27, 2014

(54) INTERPOSER HAVING EMBEDDED MEMORY CONTROLLER CIRCUITRY

(71) Applicant: ADVANCED MICRO DEVICES, INC., Sunnyvale, CA (US)

(72) Inventors: Andrew G. Kegel, Redmond, WA (US); Gabriel H. Loh, Bellevue, WA (US)

(73) Assignee: ADVANCED MICRO DEVICES, INC., Sunnyvale, CA (US)

(21) Appl. No.: 13/627,895

(22) Filed: Sep. 26, 2012

(51) Int. Cl. H01L 23/535; G06F 12/00; H01L 21/768

(52) U.S. Cl. 711/154; 257/774; 438/667; 257/E23.168; 257/E21.577; 711/E12.001

(57) ABSTRACT

A system is provided that includes an interposer having memory controller circuitry embedded therein. The interposer includes conductive vias that are embedded within and that extend through the interposer. The memory controller circuitry can be coupled to some of the conductive vias. In some implementations, other ones of the conductive vias are configured to be coupled to a processor and a memory module that can be mounted along a surface of the interposer. Conductive links are disposed on a surface of the interposer to couple the processor and the memory module to the memory controller circuitry.

### TECHNICAL FIELD

Embodiments of the subject matter described herein relate generally to integrated circuit mounting technology. More particularly, embodiments of the subject matter relate to interposers that are configured to have processors and memory modules mounted thereon, and methods for operating systems that include such interposers with processors and memory modules mounted thereon.

### BACKGROUND

In modern computer systems there are many different ways for mounting and interconnecting a processor and memory devices.

One traditional technique involves mounting a semiconductor integrated circuit package to conductive traces on a printed circuit board. One drawback of this approach is that the package has relatively large pins that have significant capacitance and inductance. As such relatively large drive transistors are required to drive signals over the pins.

Another technique is commonly referred to as die stacking. Die Stacking is the process of mounting multiple chips on top of each other within a single semiconductor package so that they occupy less space and/or have greater connectivity. The dies are interconnected using conductive vias that are sometimes referred to as through-silicon vias (TSVs). Die stacking significantly increases the amount of silicon chip area that can be housed within a single package of a given footprint.

More recently, a die-mounting technology called an interposer has been developed. An interposer serves as a base upon which semiconductor dies (e.g., integrated circuit packages) can be mounted. An interposer includes conductive vias that can be used to provide electrical connections between the semiconductor dies. For example, in some applications, semiconductor chips, such as memory modules and processors, can be mounted on an interposer.

An interposer is typically a substrate made of semiconductor material, such as silicon or other commonly used semiconductor materials. An interposer can include conductive traces that are etched on its exposed surfaces, as well as conductive vias that are formed in through holes that extend through the substrate. The conductive traces can be connected to the conductive vias, and the conductive vias can be used for interconnection routing between the various die that are mounted on the surfaces of the interposer. In most applications, the interposer does not include active elements or devices, such as transistors and diodes.

One advantage of interposer technologies is that the interposer expands and contracts at the same (or a similar) rate as the semiconductor integrated circuits since both are fabricated from silicon based materials. Another advantage of using an interposer is that it allows multiple incompatible technologies to be mounted on the same interposer. In addition, the conductive vias have less capacitance, which allows processor and memory to be interconnected at higher speeds for better performance. At the same time, using an interposer requires certain modifications to the processor and memory chips to take advantage of the die-stacking electrical environment.

For example, to mount commodity memory chips on an interposer, the memory chips need to be modified. In addition, because each type of memory technology has its own memory controller, different memory controllers must be implemented to handle different memory types that use different memory controller designs. At the same time, modifying the design processor chips to interface with different memory controller and memory types is a complex and expensive task. These modifications can negate some of the economic advantages of using commodity memory chips, which makes die-stacking less attractive.

In some cases, different memory controllers can be designed into the processor chips that handle different memory types on a selectable basis, but this usually means that gates are included in the design that consume area while providing no function (e.g., two sets of memory controller circuitry must be implemented yet only one of the sets of circuits is used in a given system).

Another option would be to design a multi-protocol memory controller that is compliant with multiple memory protocols. Again, this is a complex and expensive task.

There is a need in the art for improved interposers, packaging systems and methods that can be used to mount dies on such interposers.

### BRIEF SUMMARY OF EMBODIMENTS

Memory controller circuitry interfaces between a processor and one or more memory devices, and manages the flow of data between the processor and the memory device(s). Memory controller circuitry is often fabricated as a separate discrete memory controller chip (e.g., on its own die) that can be implemented on a motherboard's Northbridge chip. Alternatively, in another approach, the memory controller circuitry can be fabricated on the same die (i.e., on the same chip) with the processor chip to reduce memory latency. There are advantages and drawbacks to both approaches.

For high-performance computing systems, it is desirable for the processor and memory modules to be located within close proximity for faster communication (high bandwidth). Packaging chips in closer proximity not only improves performance, but can also reduce the energy expended when communicating between the processor and memory. It would be desirable to utilize the large amount of “empty” silicon that is available in an interposer.

In accordance with some of the disclosed embodiments, memory controller circuitry can be fabricated in and embedded into the substrate of the interposer.

In accordance with one embodiment, a method is provided in which memory controller circuitry is fabricated in an interposer that includes a plurality of conductive vias that are embedded within and extend through the interposer.

In accordance with another embodiment, an interposer is provided that has a first surface and a second surface opposite the first surface. The interposer includes a plurality of conductive vias that are embedded within and that extend through the interposer from the first surface to the second surface. The interposer includes memory controller circuitry fabricated in the interposer and coupled to a first set of the conductive vias. In some embodiments, a plurality of conductive links can be formed on the first surface and coupled to the memory controller circuitry.

In accordance with some of the disclosed embodiments, a system is provided that includes an interposer having memory controller circuitry fabricated and embedded therein. The interposer includes conductive vias that are embedded within and that extend through the interposer. The memory controller circuitry can be coupled to some of these conductive vias. Other ones of the conductive vias are coupled to a processor and a memory module that can be mounted along a surface (or surfaces) of the interposer. Conductive links are formed such that they are disposed on and/or in a surface (or surfaces) of the interposer to couple the processor and the memory module to the memory controller circuitry.

In accordance with some other embodiments, other die can be mounted along the second surface of the interposer, and can be coupled to the memory controller circuitry.

In accordance with other embodiments, methods of operating a system are provided where the system comprises an interposer having memory controller circuitry fabricated therein, a processor mounted along a surface of the interposer and a memory module mounted along a surface of the interposer, a first conductive link formed in or on the interposer and being arranged to couple the processor to the memory controller circuitry, and a second conductive link formed in or on the interposer and being arranged to couple the memory module to the memory controller circuitry. The method of operating comprises communicating, from the processor to the memory controller circuitry over the first conductive link, a request to access a memory location in the memory module, and accessing the memory location in the memory module via the memory controller circuitry over the second conductive link. In one embodiment, the communicating includes communicating, from the processor to the memory controller circuitry over the first conductive link, a request to read data from a memory location in the memory module, and accessing the memory location in the memory module includes reading, at the memory controller over the second conductive link, the data from the memory location in the memory module. The data read from the memory location can then be communicated from the memory controller circuitry to the processor over the first conductive link. In another embodiment, the communicating includes communicating, from the processor to the memory controller circuitry over the first conductive link, data to be written to a memory location in the memory module, and accessing the memory location in the memory module comprises writing the data from the memory controller the memory location in the memory module over the second conductive link.

This summary is provided to introduce a selection of concepts in a simplified form that are further described below in the detailed description. This summary is not intended to identify key features or essential features of the claimed subject matter, nor is it intended to be used as an aid in determining the scope of the claimed subject matter.

### BRIEF DESCRIPTION OF THE DRAWINGS

A more complete understanding of the subject matter may be derived by referring to the detailed description and claims when considered in conjunction with the following figures, wherein like reference numbers refer to similar elements throughout the figures.

FIG. 1 is a block diagram of system in accordance with one of the disclosed embodiments.

FIG. 2 is a cross sectional view of the system that is illustrated in FIG. 1 taken along line 2-2′.

FIG. 3 is a block diagram of system in accordance with one of the disclosed embodiments.

FIG. 4 is a block diagram of system in accordance with one implementation of some of the disclosed embodiments.

FIG. 5 is a block diagram of system in accordance with one of the disclosed embodiments.

FIG. 6 is a cross sectional view of the system that is illustrated in FIG. 1 taken along line 2-2′ in accordance with another exemplary embodiment.

### DETAILED DESCRIPTION OF EMBODIMENTS

The following detailed description is merely illustrative in nature and is not intended to limit the embodiments of the subject matter or the application and uses of such embodiments. As used herein, the word “exemplary” means “serving as an example, instance, or illustration.” Any implementation described herein as exemplary is not necessarily to be construed as preferred or advantageous over other implementations. Furthermore, there is no intention to be bound by any expressed or implied theory presented in the preceding technical field, background, brief summary or the following detailed description.

Techniques and technologies may be described herein in terms of functional and/or logical block components and with reference to operations, processing tasks, and functions that may be performed by various components or devices. It should be appreciated that the various block components shown in the figures may be realized by any number of hardware components configured to perform the specified functions. For example, an embodiment of a system or a component may employ various integrated circuit components, e.g., memory elements, processing elements, logic elements, or the like, which may carry out a variety of functions under the control of one or more processors.

For the sake of brevity, conventional techniques related to mounting die on interposers, and other functional aspects of the die that are mounted on interposers may not be described in detail herein. Furthermore, the connecting lines shown in the various figures contained herein are intended to represent example functional relationships and/or physical couplings between the various elements. It should be noted that many alternative or additional functional relationships or physical connections may be present in an alternative embodiments.

The following description refers to elements being “connected” or “coupled” together. As used herein, unless expressly stated otherwise, “coupled” means that one element is directly or indirectly joined to (or directly or indirectly communicates with) another element, and not necessarily mechanically. Likewise, unless expressly stated otherwise, “connected” means that one element is directly joined to (or directly communicates with) another element, and not necessarily mechanically. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “below,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. Further, certain terminology may also be used in the following description for the purpose of reference only, and thus are not intended to be limiting. For example, terms such as “first,” “second,” and other such numerical terms referring to elements or features do not imply a sequence or order unless clearly indicated by the context.

It is understood that the following disclosure provides many different embodiments, or examples, for implementing different features of the invention. Specific examples of components and arrangements are described below to simplify the present disclosure. These are, of course, merely examples and are not intended to be limiting.

In addition, like reference numerals are used throughout the figures to designate similar or equivalent elements. While the present disclosure may repeat reference numerals and/or letters in the various examples, this repetition is for the purpose of simplicity and clarity and does not in itself dictate a relationship between the various embodiments and/or configurations discussed. The figures are not drawn to scale and they are provided merely to illustrate some example implementations of the disclosed embodiments.

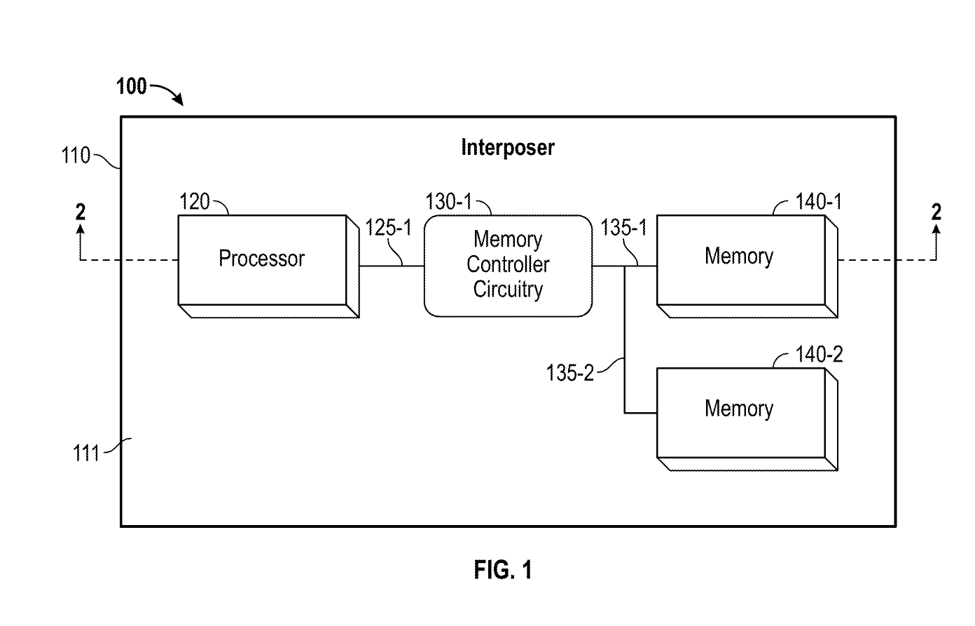

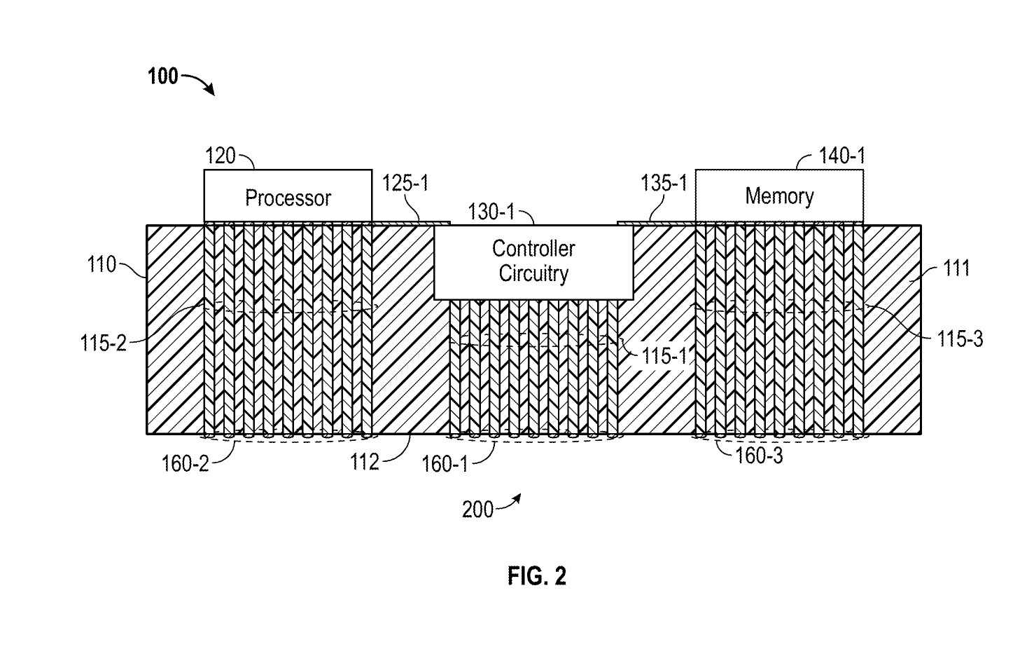

FIG. 1 is a block diagram of system 100 in accordance with one of the disclosed embodiments. FIG. 2 is a cross sectional view 200 of the system 100 that is illustrated in FIG. 1 taken along line 2-2′. In this embodiment, the system 100 includes an interposer 110, a processor 120, a first memory module 140-1 and optionally a second memory module 140-2, and memory controller circuitry 130-1. For illustration purposes, the processor 120, first memory module 140-1, second memory module 140-2 are illustrated using raised rectangular shapes to indicate that they are separate die/chips that are mounted or “stacked” on a first surface 111 of the interposer 110, whereas the memory controller circuitry 130-1 is illustrated using non-raised or flat shape to indicate that it is fabricated in the interposer 110 (e.g., integrated and embedded in the interposer 110). The terms “die,” “chip” and “microchip are used interchangeably herein.

The interposer 110 can be fabricated from a layer of semiconductor material such as a bulk silicon substrate. The interposer 110 can be made of any suitable semiconductor material including a silicon material, where the term “silicon material” is used herein to encompass the generally monocrystalline and relatively pure silicon materials typically used in the semiconductor industry, as well as silicon admixed with other elements such as germanium, carbon, and the like. Alternatively, semiconductor material can be germanium, gallium arsenide, or the like. When the interposer 110 is fabricated using a semiconductor material similar to the semiconductor materials used to fabricate the processor and the memory modules, one advantage is that the interposer, processor, and memory modules are thermally matched (e.g., coefficient of expansion are closely matched). In other implementations, the substrate can also include dielectric material(s) and/or other conductive material(s).

The interposer 110 has opposing surfaces which include a first surface 111 (or first side 111) and a second surface 112 (or second side 112). Although not illustrated, in some implementations, the interposer 110 may have active and passive devices built on one or both surfaces 111 and 112. For example, the interposer 110 can include simple passive devices such as resistors, capacitors, or more complex active devices such as transistors, diodes, thyristors, or circuits (e.g., driver circuits) that are fabricated in the interposer.

As illustrated in FIG. 2, the interposer 110 includes a plurality of conductive vias 115 embedded within the interposer 110. As used herein, a “conductive via” is conductive structure that extends through a substrate (e.g., at least from a top surface of the substrate to a bottom surface of the substrate) such that it is embedded in the substrate. The conductive vias are coupled to electrical contacts (referred to herein as conductive connections, which in one implementation are micro bumps), which can be used couple various processors, memory modules (and other integrated circuit devices) that are mounted on surfaces of the interposer 110. The conductive vias 115 are sometimes referred to in the art as through-substrate vias (TSVs). The conductive vias 115 penetrate through substrate material of the interposer 110, and are used to electrically inter-couple features on opposite sides of the substrates.

The conductive vias 115 can be formed using any known fabrication processing technology.

In one embodiment, the conductive vias 115 can be formed by forming openings or trenches in and/or through a substrate (e.g., by Reactive Ion Etching (RIE), laser drilling, wet chemical etch, or another etching process). Insulator materials can then be deposited in the openings to form liners (not shown) on the surface of each of the conductive vias 115 to electrically isolate each of the conductive vias 115 from the substrate that the conductive vias 115 are embedded in. The insulator materials can be deposited using techniques such as physical vapor deposition (PVD), chemical vapor deposition (CVD), printing, sintering, or thermal oxidation. Conductive materials can then be deposited to fill the insulator-lined openings. The conductive materials can be deposited using techniques such as evaporation, electrolytic plating, electroless plating, screen printing, physical vapor deposition (PVD), or any other suitable deposition process for depositing conductive materials. Although not illustrated, those skilled in the art will appreciate that the conductive vias 115 can be multilayered conductive structures that can include isolation and barrier layers disposed between the conductive layers and the substrate material of the interposer 110. In one implementation, the conductive vias include copper material. In other implementations, the conductive vias can include materials, such as tungsten, aluminum, copper, titanium, tantalum, titanium nitride, tantalum nitride, nickel silicide, cobalt silicide, other proper conductive materials, and/or combinations thereof. A planarization process (e.g., chemical-mechanical polishing (CMP)) can then be performed to remove excess portions of the insulator and conductive materials. The remaining portions of the conductive material in the substrate form the conductive vias 115.

The conductive vias 115 can be logically grouped into different sets (each being encircled by dashed-line ellipse) including a first set of conductive vias 115-1, a second set of the conductive vias 115-2, a third set of the conductive vias 115-3, and additional sets that are not illustrated for sake of clarity.

The interposer 110 can also include a plurality of conductive connections 160 on the first surface 111 of the interposer 110, and on a second surface 112 of the interposer 110 that is opposite the first surface 111. Each of the conductive vias 115 can have one of the conductive connections 160 coupled to it. For example, a first set of conductive connections 160 can be coupled to the first set of the conductive vias 115-1, a second set of the conductive connections 160 can be coupled to the second set of the conductive vias 115-2, and a third set of the conductive connections 160 can be coupled to the third set of the conductive vias 115-3, and so on. In addition, the conductive vias 115 and the conductive connections 160 are illustrated for purposes of illustration only, and that in a practical implementation, an interposer 110 can have few or more of each depending on the implementation. Further, it is noted that the conductive connections 160 can be any known type of conductive connection including, but not limited to, conductive micro-bumps, balls, terminals, bond pads, etc. In one implementation, the conductive connections 160 can be solder bumps, such as eutectic solder bumps. In alternative implementations, the conductive connections 160 can be fabricated using at least one material, such as copper (Cu), aluminum (Al), gold (Au), silver (Ag), nickel (Ni), tungsten (W), and alloys thereof such as aluminum copper (AlCu), a lead-free alloy (e.g., a tin/silver/copper (Sn/Ag/Cu) alloy, or other lead-free alloys), a lead-containing alloy (e.g., a lead/tin (Pb/Sn) alloy), conductive polymer, or any combinations thereof (e.g., aluminum silicon copper (AlSiCu)).

Although not illustrated, the processor 120 and memory modules 140 each include a semiconductor substrate with contact pads located on a surface of the substrate. The contact pads can be mounted to the conductive connections 160 on a surface of the interposer that are conductively connected to the conductive vias 115. As used herein, two elements are “conductively connected” to each other if there exists a conductive path between the two elements to allow conduction of electricity.

In the example illustrated in FIG. 1, processor 120 is illustrated as being generic processor chip. As used herein, the term “processor” refers to hardware within a computer system, which is designed execute a sequence of stored instructions of a computer program that is stored in some kind of memory by performing the basic arithmetical, logical, and input/output operations of the system. A processor can be, for example, a general-purpose microprocessor. A microprocessor is a multipurpose, programmable device that accepts digital data as input, processes it according to instructions stored in a memory, and provides results as output. A microprocessor can be implemented using one or more large scale integrated circuits that are housed or packaged in a microchip that includes hundreds of connecting pins.

In this regard, the processor 120 can be any known type of computer processor (e.g., a central processor unit (CPU), a heterogeneous processor unit, an accelerated processing unit (APU), graphics processing unit (GPU), a network processing unit, a security processing unit, a compression processing unit, etc.). An accelerated processing unit (APU) refers to a processing system that includes additional processing capability designed to accelerate one or more types of computations outside of a CPU. This may include a graphics processing unit (GPU) used for general-purpose computing (GPGPU), reconfigurable processing unit, a field-programmable gate array (FPGA), or similar specialized processing system. An APU can also refer to a processing device which integrates a CPU and a GPU on the same die, thus improving data transfer rates between these components while reducing power consumption. APUs can also include video processing and other application-specific accelerators. A processor may also refer to a graphics processing unit (GPU) (also occasionally called visual processing unit (VPU)), which is a specialized electronic circuit designed to rapidly manipulate and alter memory in such a way so as to accelerate the building of images in a frame buffer intended for output to a display. GPUs are used in embedded systems, mobile phones, personal computers, workstations, and game consoles.

In addition, depending on the implementation, the number of processor chips mounted along the interposer 110 can vary, as can the types of processor chips that are mounted along the interposer 110.

Depending on the implementation, the type and number of memory modules can also vary. In the example illustrated in FIG. 1, blocks first memory module 140-1 and second memory module 140-2 are illustrated as being generic memory chips. As used herein, the term “memory” refers to one or more physical devices used to store programs (sequences of instructions) or data (e.g. program state information) on a temporary or permanent basis for use in a computer or other digital electronic device. The term “memory” is often, but not always, associated with addressable semiconductor memory (e.g., integrated circuits consisting of silicon-based transistors) that is commonly used in computers and other digital electronic devices. As is known in the art, a semiconductor memory is organized into memory cells, each storing one binary bit (0 or 1), and the memory cells are grouped into words that can be accessed by a binary address.

As used herein, the term “memory module” refers to any type of memory chip or die that includes circuitry for implementing a memory or storage device. As used herein, the term “die” refers to semiconducting material in/on which a given functional circuit is fabricated. A memory module can be any type of integrated circuit memory, and can be a die, a die that is encapsulated within a package, or a die that is encapsulated within a package with other circuitry. As used herein, a package “encapsulates” a die if all outer surfaces of the die is located within inner surfaces of the package.

The first memory module 140-1 (and any other memory module described herein) can be any type or class of memory device unless specifically limited to being a particular type of memory device 140. As is known in the art, there are two main types of semiconductor memory: volatile and non-volatile. Non-volatile memory is computer memory that can retain the stored information even when not powered. Examples of non-volatile memory include read-only memory (ROM) such as programmable read only memory (PROM), erasable programmable read only memory (EPROM), and electrically erasable programmable read-only memory (EEPROM) or Flash ROM, etc. Volatile memory is computer memory that requires power to maintain the stored information. Most modern semiconductor volatile memory is either Static RAM (SRAM) or dynamic RAM (DRAM). SRAM retains its contents as long as the power is connected and is easy to interface to, whereas DRAM is more complicated to interface to (and control) and needs regular refresh cycles to prevent its contents being lost. Examples of DRAM include Video DRAM (VRAM), Fast page mode DRAM (FPM DRAM), Extended data out DRAM (EDO DRAM), Burst EDO DRAM (BEDO DRAM), Multibank DRAM (MDRAM), Synchronous Graphics RAM (SGRAM), Synchronous Dynamic RAM (SDRAM), Single Data Rate (SDR) DRAM, Double Data Rate (DDR) DRAM (including DDR SDRAM, DDR2 SDRAM, DDR3 SDRAM, and DDR4 SDRAM), Direct Rambus DRAM (DRDRAM), Reduced Latency DRAM (RLDRAM), etc. In some implementations, memory module can also be a single in-line pin package (SIPP) memory module, a single in-line memory module (SIMM), a dual in-line memory module (DIMM), etc. Other volatile memory technologies include magnetic RAM (MRAM), zero-capacitor RAM (Z-RAM) sometimes called 1T DRAM or Advanced-Random Access Memory (A-RAM), Thyristor RAM (T-RAM), Twin Transistor RAM (TTRAM), Pseudostatic RAM (PSRAM), etc.

The processor 120 and memory modules 140 can be mounted on the first surface 111 with their circuit sides face-down (active circuits facing downward) to the interposer 110 (e.g., by a ball-grid array (BGA), micro-bump bonding (MBB), or controlled collapse chip connections (C-4), etc.). Similarly, any die that are mounted on the second surface of the interposer 110 will have their active circuits facing upward and can be mounted using the same or similar connection technologies.

In accordance with the disclosed embodiments, the interposer 110 includes memory controller circuitry 130-1 that is fabricated in the semiconductor material of the interposer 110 such that it is embedded in the interposer 110 and coupled to the first set of the conductive vias 115-1. As used herein, the term “memory controller circuitry” refers to electronic circuitry which processes communications between a processor and memory module(s), and manages flow of data between the processor from the memory module(s). Among other things, the memory controller circuitry 130-1 is responsible for performing functions such as signal and protocol conversions, logic for reading from and writing to memory, error correction, refresh operations, buffering, power management, timing, and multiplexing. Integration of the memory controller circuitry 130-1 into the interposer 110 can improve performance and/or reliability characteristics of the system 100, while reducing power consumption of the system 100. Because connectors are eliminated, electrical parameters can be better controlled and higher speed links between the processor 120, memory controller circuitry 130, and memory modules 140 can be designed. In addition, manufacturing complexity can be reduced since custom logic/circuits do not need to be added to the individual stacked chips (e.g., processor 120 and memory module(s) 140).

In some implementations, the first memory controller circuitry 130-1 can be fabricated in the interposer 110 such that is extends above the surface of the interposer 110, in which case it can be said that the first memory controller circuitry 130-1 is formed in and on/above the interposer 110. The first memory controller circuitry 130-1 (and any other 130 described herein) can include circuitry used to implement a memory controller (or memory buffer logic) that is integrated within the interposer 110, and interfaces with the processor 120 and the first memory module 140-1 and the second memory module 140-2 when implemented. As will be explained below, implementing the first memory controller circuitry 130-1 on the interposer can allow for the processor 120 and the first memory module 140-1 (and any other memory chips) to use standardized interfaces (e.g., commodity memory chips) and still benefit from die-stacking technology.

As illustrated in FIGS. 1 and 2, the processor 120 can be mounted along a first surface of the interposer 110 and coupled to the second set of the conductive vias 115-2, and the first memory module 140-1 can be mounted along the first surface of the interposer 110 and coupled to the third set of the conductive vias 115-3.

In order to achieve high speed transmission between the processor, memory controller circuitry and memory modules, fine conductive links 125-1, 135-1 are formed on the surface of the interposer by depositing and patterning conductive materials using any known fabrication techniques. As used herein, “conductive links” are patterned conductive structures or wiring lines. Depending on the implementation, the conductive links (e.g., lines and/or pads) can be formed on and/or in the surfaces of the interposer 110. For example, a first conductive link 125-1 can be formed along (e.g., in and/or on) the first surface of the interposer 110 such that it is arranged to couple the processor 120 to the first memory controller circuitry 130-1. Similarly, a second conductive link 135-1 can be formed in or on the first surface of the interposer 110 such that it is arranged to couple the first memory module 140-1 to the first memory controller circuitry 130-1. The particular way that the first conductive link 125-1 couples the processor 120 to the first memory controller circuitry 130-1, and the particular way that the second conductive link 135-1 couples the first memory module 140-1 to the first memory controller circuitry 130-1 can vary depending on the implementation. The conductive links 125-1, 135-1 can be electrically coupled to the conductive vias 115 and/or contact points (not illustrated) and/or other surface connections (not illustrated) that are coupled to the first memory controller circuitry 130-1, the processor 120 and/or the first memory module 140-1 so that the conductive links 125-1, 135-1 couple the first memory controller circuitry 130-1 to the processor 120 and the first memory module 140-1, respectively.

In one non-limiting embodiment that is illustrated in FIG. 1, the system 100 can also optionally include the second memory module 140-2 mounted along the first surface of the interposer 110. Although not illustrated in the drawings, the second memory module 140-2 can be coupled to a fourth set of the conductive vias 115 (not shown). When the second memory module 140-2 is implemented, the system 100 can include a third conductive link 135-2 formed in or on the first surface of the interposer 110 such that the third conductive link 135-2 is arranged to couple the second memory module 140-2 to the first memory controller circuitry 130-1.

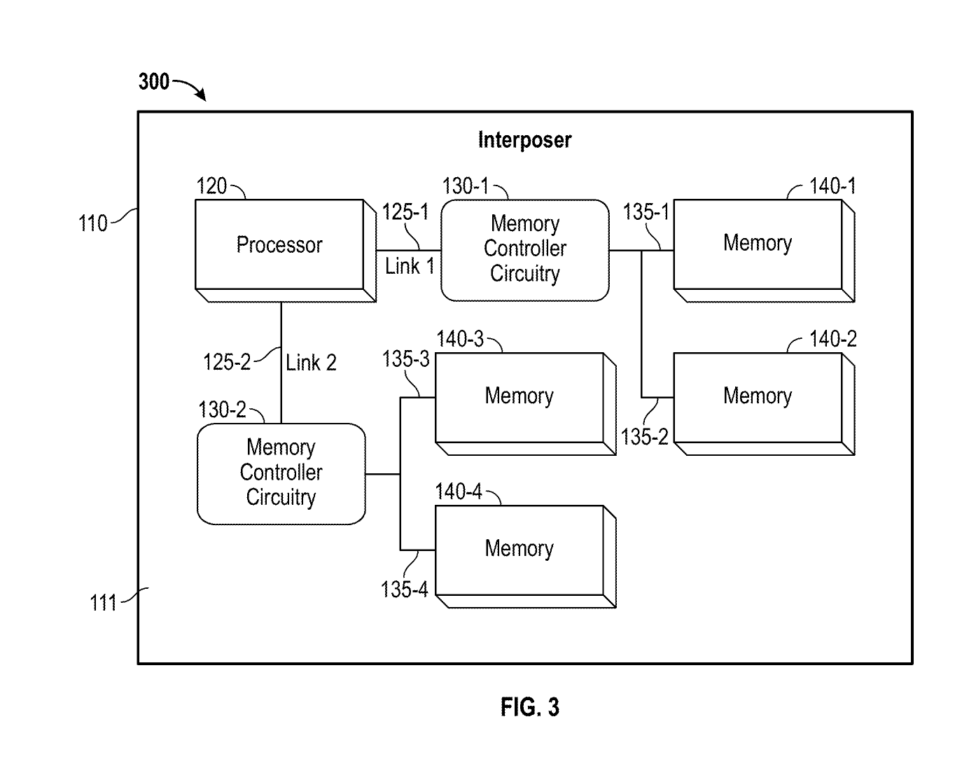

FIG. 3 is a block diagram of system 300 in accordance with one of the disclosed embodiments. The embodiment illustrated in FIG. 3 includes some of the same elements illustrated in FIG. 1, and for sake of brevity the description of those elements will not be repeated.

In this embodiment, the system 300 further includes a second memory controller circuitry 130-2 fabricated in the interposer 110, a third memory module 140-3 mounted along the first surface of the interposer 110, and optionally a fourth memory module 140-4 mounted along the first surface of the interposer 110. It is noted that in general, the interposer 110 is typically large enough so that multiple different sets of memory controller circuitry could be integrated into the interposer 110 depending on the requirements of a particular design.

Each type of memory requires its own memory controller circuitry; different interposers can be manufactured that include specific memory controller circuitry. Some interposers can include circuitry for multiple different memory controllers. Some embodiments can integrate any number of memory controller circuitry modules in the interposer 110 that are designed to handle different types of memory (DDR2, DDR3, etc.). In addition, when a memory-buffer-link (MBL) type of interface is implemented at the processor 120, there are even more implementation options. For example, the memory controller would be capable of issuing different types of memory protocols (e.g., DDR2 or DDR3 or MBL) to handle the different types of memory. Integrating circuitry for multiple memory controllers into the interposer allows a processor to connect to many different types of memory technologies. This is desirable in situations where a processors needs to access multiple different types of memory or storage.

In addition, although not illustrated in FIG. 3, its noted that the interposer 110 can include a fifth set of conductive vias 115, a sixth set of conductive vias 115, and a seventh set of the conductive vias 115, and similar to the manner illustrated in FIG. 2, the second memory controller circuitry 130-2 can be coupled to the fifth set of the conductive vias 115, a third memory module 140-3 can coupled to the sixth set of the conductive vias 115, and the fourth memory module 140-4 can be coupled to the seventh set (not illustrated) of the conductive vias 115. Further, as illustrated in FIG. 3, the system 300 also includes another first conductive link 125-2, another second conductive link 135-3, and another third conductive link 135-4 formed in or on the first surface of the interposer 110. The another first conductive link 125-2 is arranged to couple the processor 120 to the second memory controller circuitry 130-2, the another second conductive link 135-3 is arranged to couple the third memory module 140-3 to the second memory controller circuitry 130-2, and the another third conductive link 135-4 is arranged to couple the fourth memory module 140-4 to the second memory controller circuitry 130-2.

Further, the first memory controller circuitry 130-1 and its associated memory modules can be the same type as or a different type than the second memory controller circuitry 130-2 and its associated memory modules. For instance, in one implementation of FIG. 3, the first memory module 140-1 and second memory module 140-2 can be a first type of memory (e.g., DRAM), and the first memory controller circuitry 130-1 can be controller for controlling that first type of memory, and the third memory module 140-3 and fourth memory module 140-4 can be a second type of memory (e.g., flash memory), and the second memory controller circuitry 130-2 a controller that is designed for controlling that second type of memory.

As such, depending on the implementation, the electrical and protocol connections over first conductive link 125-1 and another first conductive link 125-2 can be either the same or different, depending on whether or not the first memory module 140-1, the second memory module 140-2, the third memory module 140-3 and the fourth memory module 140-4 are the same type of memory technology or different types of memory technologies. Similarly, depending on the implementation, the first memory controller circuitry 130-1 and the second memory controller circuitry 130-2 can be either the same or different, depending on whether or not the first memory module 140-1, the second memory module 140-2, the third memory module 140-3 and the fourth memory module 140-4 are implemented using the same type of memory technology or different types of memory technologies.

Moreover, its noted that although four memory modules 140 are illustrated in FIG. 3 (with two coupled to each of the first memory controller circuitry 130-1 and the second memory controller circuitry 130-2) for sake of showing one example implementation, this embodiment is not limiting and that fewer or more memory modules could be coupled to each of the first memory controller circuitry 130-1 and the second memory controller circuitry 130-2 in other embodiments.

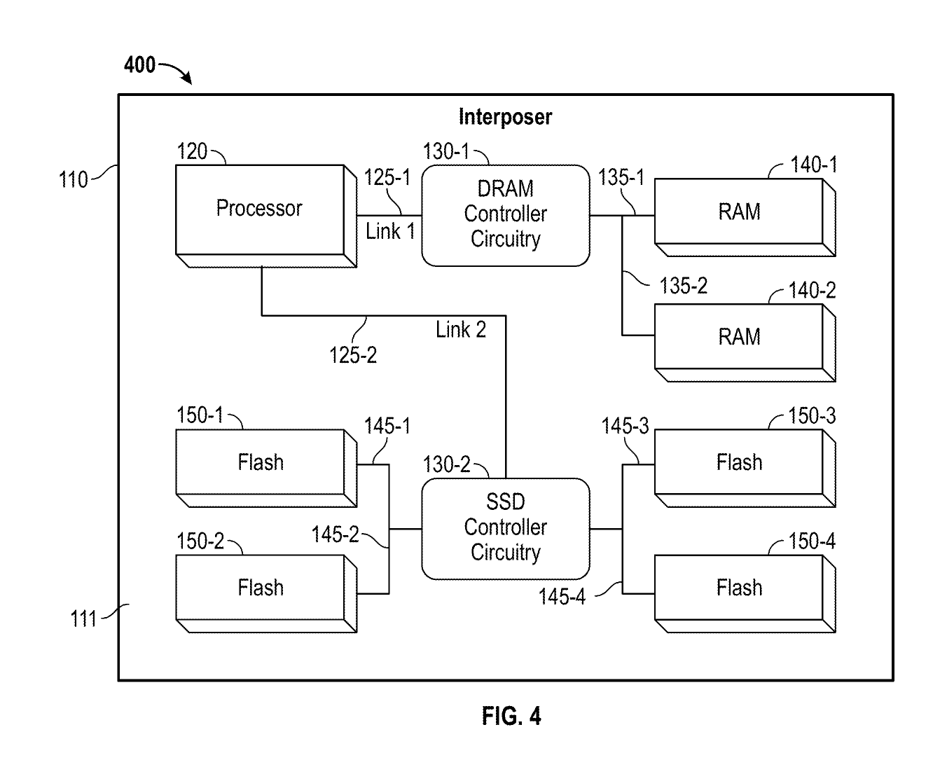

In some implementations, the interposer 110 can be designed to include multiple different types of memory controller circuitry 130 so that the same processor 120 can be interfaced to different types of memory modules 140 that implement different memory technologies that have, for example, different bit widths, different speed specifications, etc. One example implementation of a system using specific types of volatile memory will now be described below with reference to FIG. 4.

FIG. 4 is a block diagram of system 400 in accordance with one implementation of some of the disclosed embodiments. The embodiment illustrated in FIG. 3 includes some of the same elements illustrated in FIG. 1-3, and for sake of brevity the description of those elements will not be repeated. In this embodiment, the first memory module 140-1 and second memory module 140-2 are implemented as a first type of memory technology (specifically as DRAM module (or chips)), and the third memory module 140-3 and fourth memory module 140-4 are implemented as a second type of memory technology (specifically flash memory module (or chips)), and have thus been re-numbered using reference numbers 150-3 and 150-4, respectively in FIG. 4. The flash memory module 150-3 and 150-4 are coupled to the second memory controller circuitry 130-2 via conductive links 145-3, 145-4, respectively.

In addition, to illustrate that additional memory modules can be coupled to the second memory controller circuitry 130-2, additional flash memory module 150-1 and 150-2 are illustrated in FIG. 4 that are coupled to the second memory controller circuitry 130-2 via conductive links 145-1, 145-2, respectively. Although not illustrated in FIG. 4, those skilled in the art will appreciate that additional DRAM module could also be coupled to first memory controller circuitry 130-1 in other implementations.

In this implementation, the electrical and protocol connections over first conductive link 125-1 and another first conductive link 125-2 are different, and the first memory controller circuitry 130-1 is implemented as DRAM controller circuitry (e.g., for main memory) that is fabricated in the first surface 111 of the interposer 110 and interfaces with the DRAM, whereas the second memory controller circuitry 130-2 is implemented as solid-state drive (SSD) controller circuitry that is fabricated in first surface 111 of the interposer 110 and interfaces to flash memory.

As above, the processor 120, the first memory controller circuitry 130-1, the second memory controller circuitry 130-2, the first DRAM module 140-1, the second DRAM module 140-2, the flash memory module 150-1, 150-2, 150-3, and 150-4 can all be coupled to their own set of TSVs that are formed within and that extend through the interposer 110.

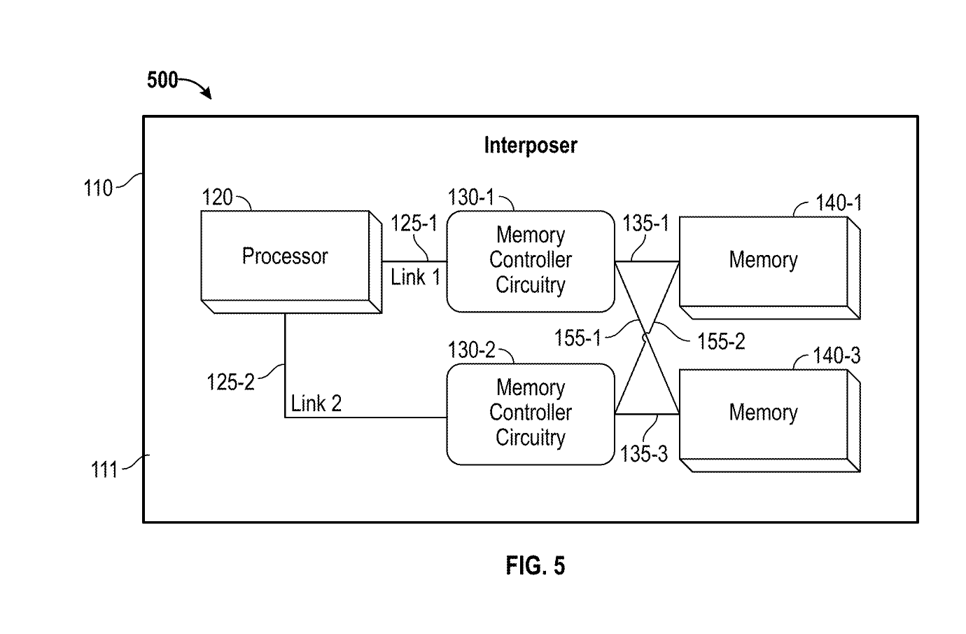

FIG. 5 is a block diagram of system 500 in accordance with one of the disclosed embodiments. The embodiment illustrated in FIG. 5 includes some of the same elements illustrated in FIGS. 1 and 3, and for sake of brevity the description of those elements will not be repeated. In this embodiment, the system 300 further includes a first redundant conductive link 155-1 and a second redundant conductive link 155-2 formed in or on the first surface of the interposer 110. The first redundant conductive link 155-1 is arranged to couple the third memory module 140-3 to the first memory controller circuitry 130-1, and the second redundant conductive link 155-2 is arranged to couple the first memory module 140-1 to the second memory controller circuitry 130-2. The first redundant conductive link 155-1 and the second redundant conductive link 155-2 provide redundancy that can allow for fault-tolerance, either at manufacturing time or during operation. For example, if the first memory controller circuitry 130-1 is faulty for some reason, the system 500 can use the path provided via another first conductive link 125-2, second memory controller circuitry 130-2 and second redundant conductive link 155-2 to access first memory module 140-1, and if the second memory controller circuitry 130-2 is faulty for some reason, the system 500 can use the path provided via first conductive link 125-1, first memory controller circuitry 130-1 and first redundant conductive link 155-1 to access third memory module 140-3. This could be done at manufacturing time to reduce manufacturing costs (fewer discarded faulty parts) or it could be done after the system is delivered to a customer.

In another alternative embodiment, not illustrated, if the processor 120 does not have two conductive links 125 available, the first memory controller circuitry 130-1 could incorporate a multiplexor function with a control line to select the appropriate conductive link (the second conductive link 135-1 or the first redundant conductive link 155-1).

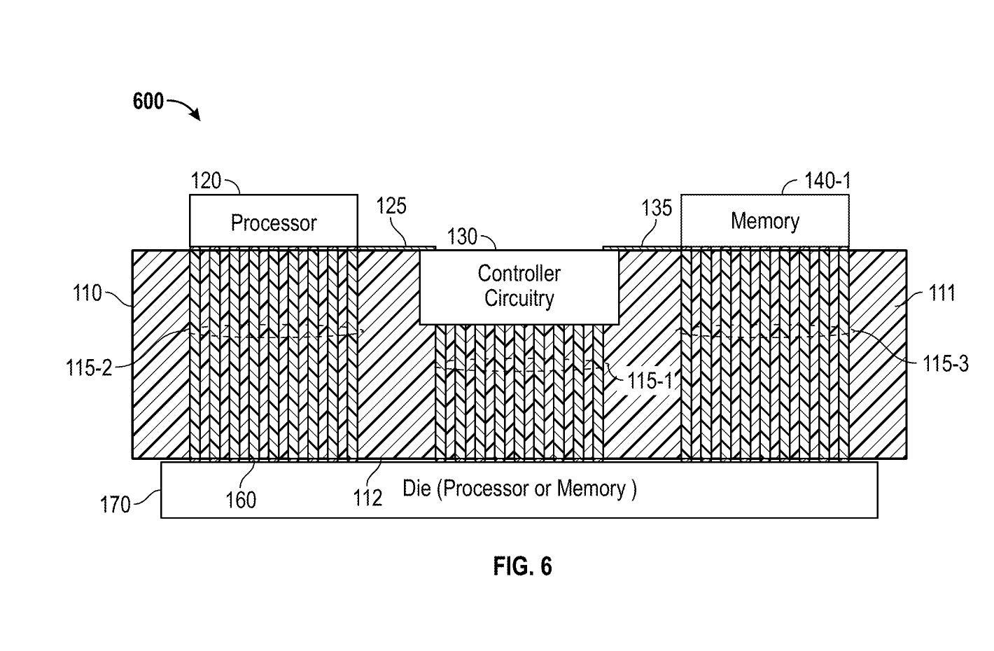

FIG. 6 is a cross sectional view of the system 600 that is illustrated in FIG. 1 taken along line 2-2′ in accordance with another exemplary embodiment. The embodiment illustrated in FIG. 6 includes some of the same elements illustrated in FIGS. 1 and 2, and for sake of brevity the description of those elements will not be repeated. In this embodiment, the system 100 further includes a die 170 mounted along a second surface 112 of the interposer 110. The die 170 is coupled to the plurality of the conductive vias 115 via the conductive connections 160. The die 170 can be any known processor or memory module. The system 600 has a compact design since dies are mounted on opposite surfaces of the interposer 110. As such, a smaller interposer can be used thereby reducing cost of the interposer. In some implementations, the conductive vias 115 can have a shorter physical length than the conductive links 125, 135 that are along the surface of the interposer 110, and in such implementations, the paths from a die 120, 140-1 mounted on the surface 11 to another die 170 mounted on the surface 112 are shorter which results in lower capacitance and a fast link between the die 120, 140-1 and the die 170.

While at least one exemplary embodiment has been presented in the foregoing detailed description, it should be appreciated that a vast number of variations exist. For example, although FIGS. 1-4 illustrate that a single processor 120 is mounted on the interposer 110, its noted that in other implementations, multiple processors, of the same of different types, can be mounted on one or more surfaces of the interposer 110 and coupled to interface with different types of memory controller circuitry that are coupled to different types of memory modules. It should also be appreciated that the exemplary embodiment or embodiments described herein are not intended to limit the scope, applicability, or configuration of the claimed subject matter in any way. Rather, the foregoing detailed description will provide those skilled in the art with a convenient road map for implementing the described embodiment or embodiments. It should be understood that various changes can be made in the function and arrangement of elements without departing from the scope defined by the claims, which includes known equivalents and foreseeable equivalents at the time of filing this patent application.

What is claimed is:

1. A system, comprising:
an interposer having a first surface and a second surface opposite the first surface, the interposer comprising:
a plurality of conductive vias that are embedded within and that extend through the interposer from the first surface to the second surface, the plurality of conductive vias including a first set of conductive vias; and
first memory controller circuitry fabricated in the interposer and coupled to the first set of the conductive vias.

2. A system according to claim 1, wherein the plurality of conductive vias further comprise: a second set of the conductive vias and a third set of the conductive vias, and further comprising:
a processor mounted along the first surface of the interposer and being coupled to the second set of the conductive vias;
a first memory module mounted along the first surface of the interposer and being coupled to the third set of the conductive vias;
a first conductive link formed in or on the first surface of the interposer, the first conductive link arranged to couple the processor to the first memory controller circuitry; and
a second conductive link formed in or on the first surface of the interposer, the second conductive link arranged to couple the first memory module to the first memory controller circuitry.

3. A system according to claim 2, wherein the plurality of conductive vias includes a fourth set of conductive vias, further comprising:
a second memory module mounted along the first surface of the interposer and being coupled to the fourth set of the conductive vias; and
a third conductive link formed in or on the first surface of the interposer, the third conductive link arranged to couple the second memory module to the first memory controller circuitry.

4. A system according to claim 2, wherein the plurality of conductive vias include a fifth set of conductive vias, and wherein the interposer further comprises: a second memory controller circuitry fabricated in the interposer and coupled to the fifth set of the conductive vias, and further comprising:
another first conductive link formed in or on the first surface of the interposer, the another first conductive link arranged to couple the processor to the second memory controller circuitry.

5. A system according to claim 4, wherein the plurality of conductive vias include a sixth set of conductive vias, and further comprising:
a third memory module mounted along the first surface of the interposer and being coupled to the sixth set of the conductive vias; and
another second conductive link formed in or on the first surface of the interposer, the another second conductive link arranged to couple the third memory module to the second memory controller circuitry.

6. A system according to claim 5, further comprising:
a first redundant conductive link formed in or on the first surface of the interposer, the first redundant conductive link arranged to couple the third memory module to the first memory controller circuitry; and
a second redundant conductive link formed in or on the first surface of the interposer, the second redundant conductive link arranged to couple the first memory module to the second memory controller circuitry.

7. A system according to claim 5, wherein the plurality of conductive vias include a seventh set of conductive vias, and further comprising:
a fourth memory module mounted along the first surface of the interposer and being coupled to the seventh set of the conductive vias; and
another third conductive link formed in or on the first surface of the interposer, the another third conductive link arranged to couple the fourth memory module to the second memory controller circuitry.

8. A system according to claim 7, wherein the first memory module comprises a first type of memory, and wherein the first memory controller circuitry comprises: a first controller for controlling the first type of memory,
wherein the third memory module comprises a second type of memory, and wherein the second memory controller circuitry comprises: a second controller for controlling the second type of memory.

9. A system according to claim 2, further comprising:
a first memory module mounted along the first surface of the interposer and being coupled to the first memory controller circuitry;
a processor mounted along the first surface of the interposer and being coupled to the first memory controller circuitry; and
a die mounted along the second surface of the interposer, the die being coupled to the first memory controller circuitry.

10. An interposer having a first surface and a second surface opposite the first surface, the interposer comprising:
a plurality of conductive vias that are embedded within and that extend through the interposer from the first surface to the second surface, the plurality of conductive vias including a first set of conductive vias; and
memory controller circuitry fabricated in the interposer and coupled to the first set of the conductive vias.

11. An interposer according to claim 10, further comprising:
a plurality of conductive links formed on the first surface that are coupled to the memory controller circuitry.

12. A method, comprising:
providing an interposer comprising a plurality of conductive vias that are embedded within and extend through the interposer; and
fabricating first memory controller circuitry in the interposer.

13. A method according to claim 12, wherein the plurality of conductive vias comprise: a first set of the conductive vias, a second set of the conductive vias and a third set of the conductive vias, wherein the first memory controller circuitry is coupled to first set of the conductive vias, and further comprising:
forming a first conductive link in or on a first surface of the interposer; and
forming a second conductive link in or on the first surface of the interposer;
mounting a processor along the first surface of the interposer such that the processor is coupled to the second set of the conductive vias and such that the first conductive link couples the processor to the first memory controller circuitry; and
mounting a first memory module along the first surface of the interposer such that the first memory module is coupled to the third set of the conductive vias, and to the first memory controller circuitry via the second conductive link.

14. A method according to claim 13, wherein the plurality of conductive vias includes a fourth set of conductive vias, further comprising:
forming a third conductive link in or on the first surface of the interposer; and
mounting a second memory module along the first surface of the interposer such that the second memory module is coupled to the fourth set of the conductive vias and to the first memory controller circuitry via the third conductive link.

15. A method according to claim 13, wherein the plurality of conductive vias include a fifth set of conductive vias and a sixth set of conductive vias, and further comprising:
forming another first conductive link in or on the first surface of the interposer and another second conductive link in or on the first surface of the interposer; and
wherein fabricating first memory controller circuitry in the interposer, comprises:
fabricating the first memory controller circuitry and second memory controller circuitry in the interposer such that the second memory controller circuitry is coupled to the fifth set of the conductive vias, wherein the another first conductive link couples the processor to the second memory controller circuitry; and
mounting a third memory module along the first surface of the interposer such that the third memory module is coupled to the sixth set of the conductive vias, and to the second memory controller circuitry via the another second conductive link.

16. A method according to claim 15, further comprising:
forming a first redundant conductive link in or on the first surface of the interposer and a second redundant conductive link in or on the first surface of the interposer;
wherein mounting a first memory module along the first surface of the interposer, comprises:
mounting the first memory module along the first surface of the interposer such that the first memory module is coupled to the third set of the conductive vias, to the first memory controller circuitry via the second conductive link, and to the second memory controller circuitry via the second redundant conductive link; and
wherein mounting the third memory module along the first surface of the interposer comprises:
mounting the third memory module along the first surface of the interposer such that the third memory module is coupled to the sixth set of the conductive vias, to the second memory controller circuitry via the another second conductive link, and to the first memory controller circuitry via the first redundant conductive link.

17. A method according to claim 15, wherein the first memory module comprises a first type of memory, and wherein the first memory controller circuitry comprises: a first controller for controlling the first type of memory,
wherein the third memory module comprises a second type of memory, and wherein the second memory controller circuitry comprises: a second controller for controlling the second type of memory.

18. A method according to claim 13, wherein the interposer comprises a second surface opposite the first surface, and further comprising:
mounting a die along the second surface such that the die is coupled to the first memory controller circuitry.

19. A method of operating a system comprising an interposer having memory controller circuitry fabricated therein, a processor mounted along a first surface of the interposer and a memory module mounted along a second surface of the interposer, a first conductive link formed in or on the interposer and being arranged to couple the processor to the memory controller circuitry, and a second conductive link formed in or on the interposer and being arranged to couple the memory module to the memory controller circuitry, the method of operating comprising:
communicating, from the processor to the memory controller circuitry over the first conductive link, a request to access a memory location in the memory module; and
accessing the memory location in the memory module via the memory controller circuitry over the second conductive link.

20. A method according to claim 19, wherein communicating, from the processor to the memory controller circuitry over the first conductive link, a request to access a memory location in the memory module, comprises:
communicating, from the processor to the memory controller circuitry over the first conductive link, a request to read data from a memory location in the memory module; and
wherein accessing the memory location in the memory module via the memory controller circuitry over the second conductive link, comprises:
reading, at the memory controller over the second conductive link, the data from the memory location in the memory module; and
further comprising:
communicating, from the memory controller circuitry to the processor over the first conductive link, the data read from the memory location.

21. A method according to claim 19, wherein communicating, from the processor to the memory controller circuitry over the first conductive link, a request to access a memory location in the memory module, comprises:
communicating, from the processor to the memory controller circuitry over the first conductive link, data to be written to a memory location in the memory module; and
wherein accessing the memory location in the memory module via the memory controller circuitry over the second conductive link, comprises:
writing the data from the memory controller the memory location in the memory module over the second conductive link.
